(19) United States
(12) Patent Application Publication
(10) Pub. No.: US 2002/0177284 A1
(43) Pub. Date: Nov. 28, 2002

(54) Method of using sacrificial spacers to reduce short channel effect

(75) Inventor: Jing-Xian Huang, Hsin-Chu (TW)

Correspondence Address: STEPHEN B. ACKERMAN, 20 MCINTOSH DRIVE, POUGHKEEPSIE, NY, 12603, US

(73) Assignee: ProMOS Technologies

(21) Appl. No.: 10/154,281

(22) Filed: May 23, 2002

(30) Foreign Application Priority Data
May 23, 2001 (TW) 90112340

(51) Int. Cl. H01L 21/336

(52) U.S. Cl. 438/303

(57) ABSTRACT

A method of forming a semiconductor device comprising the following sequential steps. A substrate having a gate electrode stack formed thereover is provided. The substrate having an exposed surface and the gate electrode stack including a lower portion with exposed side walls. A first oxide layer is formed over: the exposed side walls of the lower portion of the gate electrode stack; and the exposed surface of the substrate. A conformal dielectric layer is formed over the gate electrode stack and the first oxide layer. A sacrificial dielectric layer is formed over the conformal dielectric layer. The horizontal portions of the sacrificial dielectric layer, the conformal dielectric layer and the underlying portions of the first oxide layer are patterned to form: sacrificial dielectric spacers; L-shaped conformal dielectric spacers thereunder; and L-shaped first oxide layer spacers thereunder. Then, using the gate electrode stack and the sacrificial dielectric spacers as masks, source/drain implants are implanted adjacent the sacrificial dielectric spacers and the sacrificial dielectric spacers are removed. In an alternate embodiment, nitride spacers are formed with the L-shaped first oxide spacers with sacrificial oxide spacers being formed over the nitride spacers before formation of the source/drain implants.

### BACKGROUND OF THE INVENTION

As semiconductor devices become smaller and smaller, the devices, such as transistors, suffer severe short channel effect.

U.S. Pat. No. 5,863,824 to Gardner et al. describes a method of forming semiconductor devices using gate electrode length and spacer width for controlling drive current strength.

U.S. Pat. No. 5,846,857 to Ju describes a method of manufacturing a CMOS device employing removable sidewall spacers for independently optimized N- and P-channel transistor performance.

U.S. Pat. No. 6,156,598 to Zhou et al. describes a dual spacer process.

U.S. Pat. No. 5,789,298 to Gardner et al. describes another dual spacer process.

### SUMMARY OF THE INVENTION

Accordingly, it is an object of one or more embodiments of the present invention to provide an improved method of forming semiconductor devices while minimizing short channel effect.

Other objects will appear hereinafter.

It has now been discovered that the above and other objects of the present invention may be accomplished in the following manner. Specifically, a substrate having a gate electrode stack formed thereover is provided. The substrate having an exposed surface and the gate electrode stack including a lower portion with exposed side walls. A first oxide layer is formed over: the exposed side walls of the lower portion of the gate electrode stack; and the exposed surface of the substrate. LDD implants may then be implanted into the substrate adjacent the first oxide layer formed over the exposed side walls of the lower portion of the gate electrode stack. A conformal dielectric layer is formed over the gate electrode stack and the first oxide layer. A sacrificial dielectric layer is formed over the conformal dielectric layer. The horizontal portions of the sacrificial dielectric layer, the conformal dielectric layer and the underlying portions of the first oxide layer are patterned to form: sacrificial dielectric spacers; L-shaped conformal dielectric spacers thereunder; and L-shaped first oxide layer spacers thereunder. Then, using the gate electrode stack and the sacrificial dielectric spacers as masks, source/drain implants are implanted adjacent the sacrificial dielectric spacers and the sacrificial dielectric spacers are removed. In an alternate embodiment, nitride spacers are formed with the L-shaped first oxide spacers with sacrificial oxide spacers being formed over the nitride spacers before formation of the source/drain implants.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1 and 2 schematically illustrate a process common to both preferred embodiments of the present invention.

FIGS. 3 to 5 schematically illustrate a first preferred embodiment of the present invention in conjunction with FIGS. 1 and 2.

FIGS. 6 to 9 schematically illustrate a second preferred embodiment of the present invention in conjunction with FIGS. 1 and 2.

### DETAILED DESCRIPTION OF THE PREFERRED EMBODIMENT

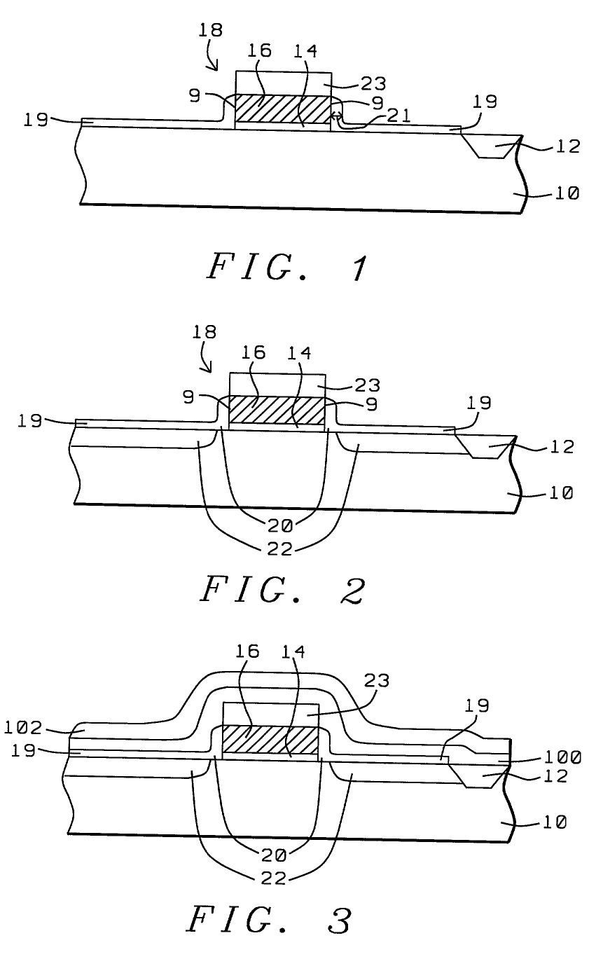

Figures Common to Both Embodiments (FIGS. 1 and 2)

Initial Structure

FIG. 1 illustrates a substrate 10 having at least one gate electrode stack 18 formed thereover. Adjacent gate electrode stacks 18 may be separated by an isolation structure 12. Gate electrode stack 18 has an underlying gate oxide layer 14, an intermediate polycide portion 16 with exposed side walls 9 and an overlying SiN cap 23.

Structure 10 is preferably a silicon or germanium substrate and isolation structure 12 is preferably a shallow trench isolation (STI) structure.

Formation of Initial Oxide Spacers 20

As shown in FIG. 1, an oxide layer 19 is thermally grown over the exposed side walls 9 of polycide portion 16 and over the exposed surface of substrate 10, covering the exposed side walls of gate oxide layer 14, to form initial sidewall spacers 20 over gate electrode stack 18.

Initial oxide spacers 20 have a lower base width 21 of preferably from about 70 to 150 Å and more preferably from about 80 to 130 Å.

Initial oxide spacers 20 serve as barriers to prevent/mitigate damage otherwise caused by subsequent implantations.

Formation of LDD Implants 22

As shown in FIG. 2 and using gate electrode stack 18 and the vertical portions of initial oxide spacers 20 as masks, LDD implants 22 are formed through the horizontal portions of oxide layer 19 and into substrate 10 adjacent initial oxide spacers 20 to a depth of preferably from about 300 to 1500 Å and more preferably from about 500 to 1200 Å. BF₂, P or As ions are preferably used to form LDD implants 22 and are preferably at a energy of preferably from about 5 to 45 keV.

First Embodiment—FIGS. (1, 2), and 3 and 5

Formation of Sacrificial Oxide Spacers 26, L-Shaped SiN Spacers 28 and L-Shaped Oxide Spacers 27

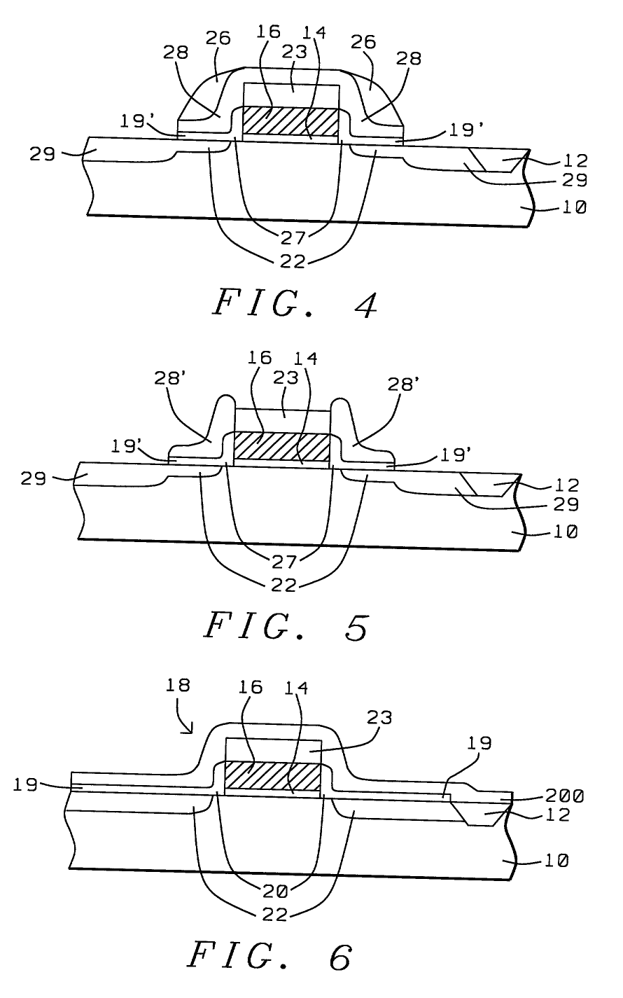

As shown in FIG. 3, a conformal SiN dielectric layer 100 is formed over gate electrode stack 18, initial oxide spacers 20, the horizontal portions of oxide layer 19 and STI 12.

A sacrificial oxide layer 102 is then formed over conformal SiN layer 100. Conformal sacrificial oxide layer 102 is preferably comprised of chemical vapor deposition (CVD) oxide (SiO₂).

Then, a conventional photolithography and etch process is performed to remove: the horizontal portions of sacrificial oxide layer 102 to form sacrificial oxide spacers 26 having a lower base width of preferably from about 80 to 300 Å and more preferably from about 100 to 200 Å; the underlying portions of conformal SiN layer 100 to form initial L-shaped SiN spacers 28 (leaving a portion of SIN layer 100 over SiN cap 23); and the underlying horizontal portions of oxide layer 19 to complete formation of L-shaped oxide spacers 27.

Source/Drain (S/D) 29 Implantation

As shown in FIG. 4, using the gate electrode stack 18 and sacrificial oxide spacers 26 as masks, source/drain (S/D) implants 29 are formed within substrate 10 adjacent sacrificial oxide spacers 26 to a depth of preferably from about 500 to 2000 Å and more preferably from about 800 to 1500 Å. BF₂, P or As ions are preferably used to form S/D implants 29 and are preferably used at an energy of preferably from about 5 to 50 keV.

Removal of Sacrificial Oxide Spacers 26

As shown in FIG. 5, the portion of SiN layer 100 overlying SiN cap 23 is removed to form the final SiN spacers 28 and sacrificial oxide spacers 26 are removed preferably using a wet clean process with chemical HF to complete the structure of the first embodiment.

Further processing may then proceed.

Thus, the effective gate length will become wider due to a sacrificial oxide spacer and in the same time without loss of gap fill for the following interlayer dielectric film. It does not change aspect ratio of gate stack to space as well.

Second Embodiment—FIGS. (1, 2) and 6 to 9

Formation of Conformal SiN Layer 200

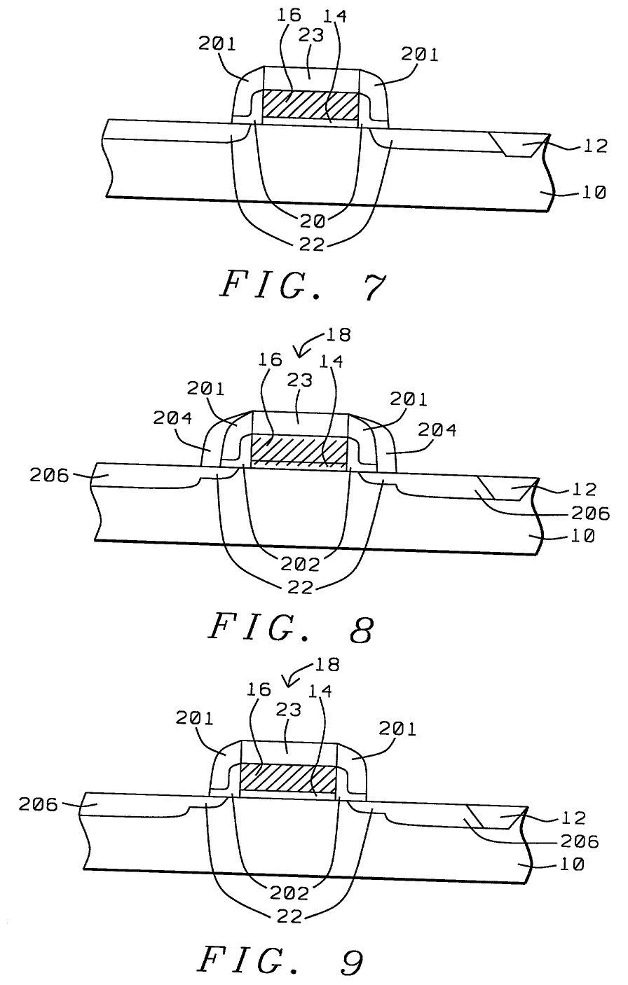

As shown in FIG. 6, a conformal SiN dielectric layer 200 is formed over gate electrode stack 18, initial oxide spacers 20, the horizontal portions of oxide layer 19 and STI 12.

Formation of Nitride Spacers 201 and L-Shaped Oxide Spacers 202

As shown in FIG. 7, the conformal SiN dielectric layer 200 is patterned with the underlying horizontal portions of oxide layer 19 to form: SiN spacers 201; and thus L-shaped oxide spacers 202.

Nitride spacers 201 have a lower base width of preferably from about 150 to 500 Å and more preferably from about 200 to 400 Å.

Formation of Sacrificial Oxide Spacers 204 Over Nitride Spacers 201

As shown in FIG. 8, sacrificial oxide (SiO₂) spacers 204 are formed over nitride spacers 201. Sacrificial oxide spacers 204 are more preferably formed of CVD oxide (SiO₂). Sacrificial oxide spacers 204 have a lower base width of preferably from about 80 to 300 Å and more preferably from about 100 to 200 Å.

Formation of Source/Drain (S/D) Implants 206

As shown in FIG. 8, using gate electrode stack 18, sacrificial oxide spacers 204 and nitride spacers 201 as masks, source/drain (S/D) implants 206 are formed within substrate 10 adjacent sacrificial oxide spacers 204 to a depth of preferably from about 500 to 2000 Å and more preferably from about 800 to 1500 Å. BF₂, P or As ions are preferably used to form S/D implants 54 and preferably used at an energy of preferably from about 5 to 50 keV.

Removal of Sacrificial Oxide Spacers 204

As shown in FIG. 9, sacrificial oxide spacers 204 are removed from nitride spacers 201 preferably using a wet clean process with chemical HF to complete the structure of the second embodiment.

Further processing may then proceed.

Thus, the effective gate length will become wider due to a sacrificial oxide spacer and in the same time without loss of gap fill for the following interlayer dielectric film. It does not change aspect ratio of gate stack to space as well.

Advantages of the Present Invention

The advantages of one or more embodiments of the present invention include effectively broadening the channel length without suffering the aspect ratio.

While particular embodiments of the present invention have been illustrated and described, it is not intended to limit the invention, except as defined by the following claims.

I claim:

1. A method of forming a semiconductor device, comprising the sequential steps of:
providing a substrate having a gate electrode stack formed thereover; the substrate having an exposed surface; the gate electrode stack including a lower portion with exposed side walls;
forming a first oxide layer over:
the exposed side walls of the lower portion of the gate electrode stack; and
the exposed surface of the substrate;
forming a conformal dielectric layer over the gate electrode stack and the first oxide layer;
forming a sacrificial dielectric layer over the conformal dielectric layer;
patterning the horizontal portions of the sacrificial dielectric layer, the conformal dielectric layer and the underlying portions of the first oxide layer to form:
sacrificial dielectric spacers;
L-shaped conformal dielectric spacers thereunder; and
L-shaped first oxide layer spacers thereunder;
using the gate electrode stack and the sacrificial dielectric spacers as masks, implanting source/drain implants adjacent the sacrificial dielectric spacers; and
removing the sacrificial dielectric spacers.

2. The method of claim 1, wherein the first oxide layer is comprised of thermal silicon oxide; the conformal dielectric layer is comprised of nitride or silicon nitride; and the sacrificial dielectric layer is comprised of oxide, silicon oxide or CVD silicon oxide.

3. The method of claim 1, wherein the first oxide layer over the exposed sidewalls of the lower portion of the gate electrode stack has a base width of from about 70 to 150 Å and the sacrificial dielectric spacers have a base width of from about 80 to 300 Å.

4. The method of claim 1, wherein the source/drain implants are formed within the substrate to a depth of from about 500 to 2000 Å at an energy of from about 5 to 45 KeV and using ions selected from the group consisting of BF₂, P and As.

5. The method of claim 1, including the step of using the gate electrode stack and the first oxide layer over the exposed sidewalls of the lower portion of the gate electrode stack as masks, implanting LDD implants into the silicon substrate adjacent the first thermal layer over the exposed sidewalls of the lower portion of the gate electrode stack before the formation of the conformal dielectric layer.

6. A method of forming a semiconductor device, comprising the sequential steps of:
providing a silicon substrate having a gate electrode stack formed thereover; the silicon substrate having an exposed surface; the gate electrode stack including a lower portion with exposed side walls;
forming a first thermal oxide layer over:
the exposed side walls of the lower portion of the gate electrode stack; and
the exposed surface of the silicon substrate;
using the gate electrode stack and the first thermal oxide layer over the exposed sidewalls of the lower portion of the gate electrode stack as masks, implanting LDD implants into the silicon substrate adjacent the first thermal layer over the exposed sidewalls of the lower portion of the gate electrode stack;
forming a conformal SiN layer over the gate electrode stack and the first thermal oxide layer;
forming a sacrificial oxide layer over the conformal SiN layer;
patterning the horizontal portions of the sacrificial oxide layer, the conformal SiN layer and the underlying portions of the first thermal oxide layer to form:
sacrificial oxide spacers;
L-shaped conformal SiN spacers thereunder; and
L-shaped first thermal oxide layer spacers thereunder;
using the gate electrode stack and the sacrificial oxide spacers as masks, implanting source/drain implants adjacent the sacrificial oxide spacers; and
removing the sacrificial oxide spacers.

7. The method of claim 6, wherein the first thermal oxide layer is comprised of thermal silicon oxide and the sacrificial oxide layer is comprised of oxide, silicon oxide or CVD silicon oxide.

8. The method of claim 6, wherein the first thermal oxide layer over the exposed sidewalls of the lower portion of the gate electrode stack has a base width of from about 70 to 150 Å and the sacrificial oxide spacers have a base width of from about 80 to 300 Å.

9. The method of claim 6, wherein the LDD implants are formed within the silicon substrate to a depth of from about 500 to 2000 Å using ions selected from the group consisting of BF₂, P and As; and the source/drain implants are formed within the silicon substrate to a depth of from about 500 to 2000 Å using ions selected from the group consisting of BF₂, P and As.

10. A method of forming a semiconductor device, comprising the sequential steps of:
providing a substrate having a gate electrode stack formed thereover; the substrate having an exposed surface; the gate electrode stack including a lower portion with exposed side walls;
forming a first oxide layer over:
the exposed side walls of the lower portion of the gate electrode stack; and
the exposed surface of the substrate;
using the gate electrode stack and the first oxide layer over the exposed sidewalls of the lower portion of the gate electrode stack as masks, implanting LDD implants into the substrate adjacent the first oxide layer over the exposed sidewalls of the lower portion of the gate electrode stack;
forming a conformal dielectric layer over the gate electrode stack and the first oxide layer;
patterning the conformal dielectric layer and the underlying portions of the first oxide layer to form:
conformal dielectric spacers; and
L-shaped first oxide layer spacers thereunder;
forming sacrificial dielectric spacers over the conformal dielectric spacers;
using the gate electrode stack, the conformal dielectric spacers and the sacrificial dielectric spacers as masks, implanting source/drain implants adjacent the sacrificial dielectric spacers; and
removing the sacrificial dielectric spacers.

11. The method of claim 10, wherein the first oxide layer is comprised of thermal silicon oxide; the conformal dielectric layer is comprised of nitride or silicon nitride; and the sacrificial dielectric spacers are comprised CVD oxide or CVD silicon oxide.

12. The method of claim 10, wherein the conformal dielectric spacers have a base width of from about 150 to 500 Å and the sacrificial dielectric spacers have a base width of from about 80 to 300 Å.

13. The method of claim 10, wherein the LDD implants are formed within the substrate to a depth of from about 500 to 2000 Å using ions selected from the group consisting of BF₂, P and As; and the source/drain implants are formed within the substrate to a depth of from about 500 to 2000 Å using ions selected from the group consisting of BF₂, P and As.

14. A method of forming a semiconductor device, comprising the sequential steps of:
providing a silicon substrate having a gate electrode stack formed thereover; the silicon substrate having an exposed surface; the gate electrode stack including a lower portion with exposed side walls;
forming a thermal oxide layer over:
the exposed side walls of the lower portion of the gate electrode stack; and
the exposed surface of the silicon substrate;
using the gate electrode stack and the thermal oxide layer over the exposed sidewalls of the lower portion of the gate electrode stack as masks, implanting LDD implants into the silicon substrate adjacent the thermal oxide layer over the exposed sidewalls of the lower portion of the gate electrode stack;
forming a conformal dielectric layer over the gate electrode stack and the thermal oxide layer; the conformal dielectric layer being comprised of nitride or silicon nitride;
patterning the conformal dielectric layer and the underlying portions of the thermal oxide layer to form:
conformal dielectric spacers; and
L-shaped thermal oxide layer spacers thereunder;
forming sacrificial dielectric spacers over the conformal dielectric spacers; the sacrificial dielectric spacers being comprised CVD oxide or CVD silicon oxide
using the gate electrode stack, the conformal dielectric spacers and the sacrificial dielectric spacers as masks, implanting source/drain implants adjacent the sacrificial dielectric spacers; and
removing the sacrificial dielectric spacers.

15. The method of claim 14, wherein the conformal dielectric layer is comprised of silicon nitride; and the sacrificial dielectric spacers are comprised CVD silicon oxide.

16. The method of claim 14, wherein the conformal dielectric spacers have a base width of from about 150 to 500 Å and the sacrificial dielectric spacers have a base width of from about 80 to 300 Å.

17. The method of claim 14, wherein the LDD implants are formed within the silicon substrate to a depth of from about 500 to 2000 Å using ions selected from the group consisting of BF₂, P and As; and the source/drain implants are formed within the silicon substrate to a depth of from about 500 to 2000 Å using ions selected from the group consisting of BF₂, P and As.
